(19) United States
(12) Patent Application Publication
(10) Pub. No.: US 2005/0082086 A1
(43) Pub. Date: Apr. 21, 2005

(54) UNBENDING PRINTED CIRCUIT BOARD

(76) Inventors: Chun-Yang Lin, Chia-Yi Hsien (TW); Shu-Chih Chen, Taipei Hsien (TW); Wen-Hsinung Shih, Chang-Hua Hsien (TW)

Correspondence Address: NORTH AMERICA INTERNATIONAL PATENT OFFICE (NAIPC), P.O. BOX 506, MERRIFIELD, VA, 22116, US

(21) Appl. No.: 10/711,795

(22) Filed: Oct. 6, 2004

(30) Foreign Application Priority Data
Oct. 15, 2003 (TW) 092128620

(51) Int. Cl. H05K 7/06

(52) U.S. Cl. 174/250; 174/255

(57) ABSTRACT

A printed circuit board (PCB) includes a plastic substrate, and a layout formed on the plastic substrate. The layout comprises a first layout and a second layout, the second layout is less dense than the first layout. The second layout comprises a pseudo-layout to prevent the PCB from being bent when heated.

### BACKGROUND OF INVENTION

1. Field of the Invention

The invention relates to a printed circuit board (PCB), and more particularly, to a PCB remaining unbent even when heated.

2. Description of the Prior Art

Every electronic product requires a PCB to carry its electric components. Thus, the quality of the PCB plays an important role in an electronic product. The technology on PCB has been fully developed, as the electronic products become compact and cheaper, the PCB is accordingly required high density, compactness and multi-layers.

Please refer to FIG. 1 showing a conventional PCB 10. The PCB 10 is single-layered, including a substrate 12 and a circuit layout 14 disposed there above. The substrate 12 is in general made of plastic being insulating from electricity and heat. The traces on the PCB 10 form the circuit layout 14. In general, the circuit layout 14 is made of copper. When manufacturing the PCB 10, a copper foil is placed on the substrate 12, and the remaining part after photolithography and etching forms the circuit layout 14. These traces transmit signals or power to the electric components installed on the PCB10. Since the circuit layout 14 and the electric components are on the same side of the substrate 12, such kind of PCB is called a single-layered PCB. If the circuit layout 14 and the electric components are installed on both sides of the substrate 12, it is called a double-layered PCB.

As the circuits of the electronic products became more and more complicated, single-layered and double-layered were no longer suitable. Thus, multi-layered PCB was developed. Please refer to FIG. 2 showing a multi-layered PCB 20. The PCB 20 includes a plurality of substrates 12a-12d. Copper foils cover each substrate 12a-12d and form the circuit layout 14s after photolithography and etching. Afterwards, the substrates 12a-12d are hot pressed together to form the multi-layered PCB 20. 4 substrates are shown in FIG. 2, which is the maximum number possible.

Please refer to FIG. 2 as well as FIG. 3, which shows the PCB 20 formed by the substrates 12a-12d shown in FIG. 2. According to the requirements of design, the circuit layout 14 on each substrate is not necessarily uniform in density. For clarity, the PCB 20 can be divided into first layouts 18a-18d and second layouts 16a-16d. As shown in FIG. 2, the second layouts 16a-16d corresponding to the substrates 12a-12d are less dense than the first layouts 18a-18d. Please notice that the density of a layout is determined from a comparative perspective on the whole PCB. Therefore, even if there are traces in region 16c, the average density of the first layouts 18a-18d is larger than that of the second layouts 16a-16d. Unfortunately, the PCB will undergo several high temperature reflow process and due to the difference of thermal expansion coefficients of the copper-made circuit layout 14 and the plastic substrate 12, the less dense second layouts 16a-16d will be bent up compared with the first layouts 18a-18d as shown in FIG. 3. For electronic products, any small deformation may cause problems on assembly. In order to solve the problem of deformation, the circuit needs to be redesigned to be more uniform, which can cause a waste in time.

### SUMMARY OF INVENTION

It is therefore a primary objective of the claimed invention to provide a PCB remaining unbent even when heated to solve the problem mentioned above.

Briefly, a printed circuit board (PCB) includes a plastic substrate, and a circuit layout formed on the plastic substrate, having a first layout and a second layout . . . . The second layout comprises a pseudo-layout to prevent the PCB from being bent when heated.

The present invention further provides a method for forming a circuit layout on a PCB substrate, the circuit layout comprising signal lines and power lines; and installing a pseudo-layout in the circuit layout to prevent the PCB from being bent when the PCB is heated.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 illustrates a conventional single-layered PCB.

FIG. 2 illustrates a conventional multi-layered PCB.

FIG. 3 illustrates the PCB formed by the substrates shown in FIG. 2.

FIG. 4 illustrates a PCB according to the present invention.

FIG. 5 is an enlarged view of the pseudo-layout.

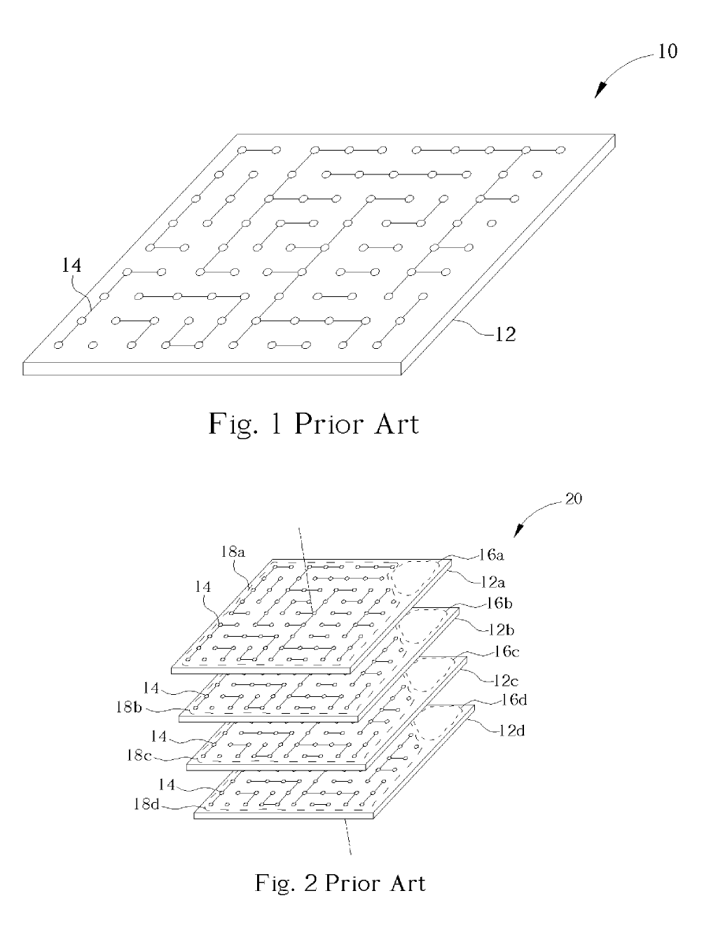

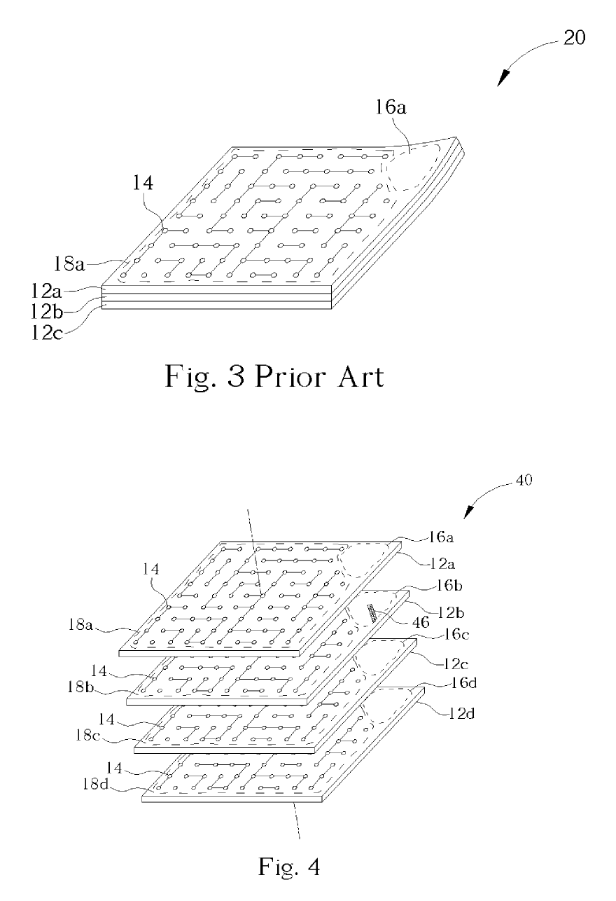

### DETAILED DESCRIPTION

Please refer to FIG. 4 showing a PCB 40 according to the present invention. The numberings of elements in FIG. 4 are the same as FIG. 2 assuming they have the same functions. The PCB 40 includes a plurality of plastic substrates 12a-12d and a plurality of circuit layouts 14 formed on the substrates 12a-12d. In general, the circuit layouts 14 are made of copper.

As described above, since the PCB requires many reflow process and the high temperature cause the deformation of the PCB, a pseudo-layout 46 is installed, for example, in the region of second layout 16b on the PCB 40. The pseudo-layout 46 is neither for transmitting signals nor power. The reason of deformation is that the average density of the second layouts 16a-16d is less than the first layouts 18a-18d. Thus the heat applied on the second layouts 16a-16d and the first layouts 18a-18d is not uniform. The pseudo-layout 46 can increase the average density of the second layouts 16a-16d. Therefore, the pseudo-layout 46 can prevent the PCB 40 from being bent when heated.

The position of the pseudo-layout 46 can be determined as follows. First, find the regions on the PCB 40 that will be bent after heating through different test processes. Of course, deformation occurs generally on low density second layouts 16a-16d. Subsequently, install the pseudo-layout 46 in the second layouts 16a-16d. As shown in FIG. 4, region 16b has the pseudo-layout 46 with a trace width of 1 mm. Certainly, the pseudo-layout 46 can be installed in any one or two, or even more of the second layouts 16a-16d. Then manufacture enforcement of the new PCB 40 with the pseudo-layout 46. Afterwards, subject the new PCB to the deformation test and adjust the amount of the pseudo-layout 46 accordingly. Repeat this cycle of testing and adjusting until the new PCB 40 is found to not bend after being heated.

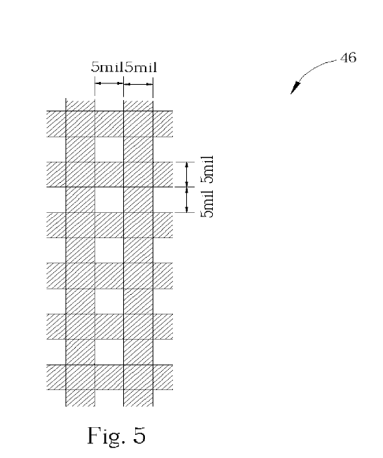

Please refer to FIG. 5 showing an enlarged view of the pseudo-layout 46. In the present invention, the pseudo-layout 46 has a plurality of parallel pseudo-traces with an interval distance of 5 mil (0.125 mm) and a width of 5 mil (0.125 mm). Certainly, the interval distance and the width of the traces are not limited to 5 mil. The pseudo-traces are the same as the typical traces on a typical circuit layout 14; however, they do not transmit signals or power but only spread the heat uniformly. It is an advantage to design the pseudo-traces in netlike circuit layout that not only the bending of the PCB can be improved, but also the netlike circuit layout forms an electric loop to prevent electromagnetic interference (EMI) with other components. Of course, the structure of the pseudo-layout 46 is not limited to a netlike structure; any other structures capable of spreading the heat uniformly also belong to the present invention. Moreover, the area and the length of the pseudo-layout can be adjusted according to the deformation of the PCB. In addition, in the present invention, the pseudo-layout 46 is isolated from the signal traces and the power traces on the PCB 40. However, the pseudo-layout 46 is not limited to that, it is not necessary to be isolated from the signal traces and the power traces on the PCB 40 if it does not influence the operation of other components on the PCB 40.

In contrast to the prior art, the PCB according to the present invention has the pseudo-layout to prevent the deformation caused by a high temperature manufacturing process. The pseudo-layout is designed to be in one or more circuit layouts so that no additional hardware or design is required. Moreover, the pseudo-layout neither cause EMI problem nor influence the operation of other components on the PCB. Therefore, the present invention is very simple and useful.

Those skilled in the art will readily observe that numerous modifications and alterations of the device may be made while retaining the teachings of the invention. Accordingly, the above disclosure should be construed as limited only by the metes and bounds of the appended claims.

1. A printed circuit board (PCB) comprising:
a plastic substrate; and
a circuit layout formed on the plastic substrate, having a first layout and a second layout,
wherein the second layout comprises a pseudo-layout to prevent the PCB from being bent when heated.

2. The PCB of claim 1 wherein density of circuits of the second layout has a lower circuit density than that of the first layout.

3. The PCB of claim 1 wherein the circuit layout comprises signal traces and power traces, the pseudo-layout is isolated from the signal traces and the power traces on the PCB.

4. The PCB of claim 1 wherein the pseudo-layout comprises a plurality of pseudo-traces neither for power nor signal transmission.

5. The PCB of claim 3 wherein the pseudo-traces are parallel to each other in a netlike structure.

6. The PCB of claim 5 wherein the parallel pseudo-traces having an interval distance, the interval distance is 5 mil.

7. The PCB of claim 5 wherein the width of the pseudo-traces is 5 mil.

8. A method for manufacturing a printed circuit board (PCB), the method comprising the steps of:
forming a circuit layout on a PCB substrate, the circuit layout comprising signal lines and power lines; and
installing a pseudo-layout in the circuit layout to prevent the PCB from being bent when the PCB is heated.

9. The method of claim 8 wherein the pseudo-layout comprises a plurality of pseudo-traces.

10. The method of claim 9 wherein the pseudo-layout is formed on the PCB and is isolated from signal lines and power lines of the circuit layout.

11. The method of claim 9 wherein the alignment of the pseudo-traces are parallel.

12. The method of claim 11 wherein the pseudo-traces have an interval distance of 5 mil.

13. The method of claim 8 wherein the width of the pseudo-traces is 5 mil.
